(19) United States
(12) Patent Application Publication
(10) Pub. No.: US 2024/0347359 A1
(43) Pub. Date: Oct. 17, 2024

(54) WAFER CARRIER HAVING INSPECTION WINDOW AND OPERATING METHOD THEREOF

(71) Applicant: TAIWAN SEMICONDUCTOR MANUFACTURING COMPANY LTD., HSINCHU (TW)

(72) Inventors: CHI JIA WANG, KAOHSIUNG CITY (TW); CHI-CHUNG JEN, KAOHSIUNG CITY (TW); KAI-HUNG HSIAO, KAOHSIUNG CITY (TW); HUI AN LI, CHANGHUA COUNTY (TW); WEN-CHIH CHIANG, HSINCHU CITY (TW)

(21) Appl. No.: 18/298,503

(22) Filed: Apr. 11, 2023

(51) Int. Cl. H01L 21/673; G02F 1/1334; G06T 7/00; H01L 21/67

(52) U.S. Cl. CPC H01L 21/67386; G02F 1/1334; G06T 7/001; H01L 21/67288; G06T 2207/30148; H01L 21/67733

(57) ABSTRACT

A method includes: receiving at least one semiconductor wafer to a wafer carrier, wherein the wafer carrier has an inspection window arranged on a side of the wafer carrier; transporting the wafer carrier between a plurality of semiconductor tools; and in response to an emergent event, switching the inspection window to a transparent mode for a predetermined period.

### BACKGROUND

Semiconductor devices are generally fabricated on the surface of a semiconductor wafer through a sequence of semiconductor manufacturing processes in different chambers or tools. Many techniques are proposed to transport the semiconductor wafer and protect the same from damage or contamination. A wafer carrier is usually employed to contain and transport the wafers during modern semiconductor manufacturing processes.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 is a schematic perspective diagrams of an automated material handling system (AMHS), in accordance with some embodiments of the present disclosure.

FIGS. 2A and 2B show schematic perspective diagrams of a wafer carrier, in accordance with some embodiments of the present disclosure.

FIG. 3 is a perspective view of a side door of the wafer carrier, in accordance with to some embodiments of the present disclosure.

FIGS. 4A and 4B show cross-section views of an inspection window in different modes, in accordance with some embodiments of the present disclosure.

FIG. 5 shows a schematic diagram of an interior view of a wafer carrier, in accordance with some embodiments of the present disclosure.

FIGS. 6A and 6B show a wafer carrier in different usage modes, in accordance with some embodiments of the present disclosure.

FIGS. 7A and 7B show a wafer carrier in different usage modes, in accordance with some embodiments of the present disclosure.

FIG. 8 is a flowchart of a method of operating a wafer carrier, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “substantial” or “substantially” generally mean within 10%, 5%, 1% or 0.5% of a given value or range. Alternatively, the terms “about,” “substantial” or “substantially” mean within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “about.” “substantial” or “substantially.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

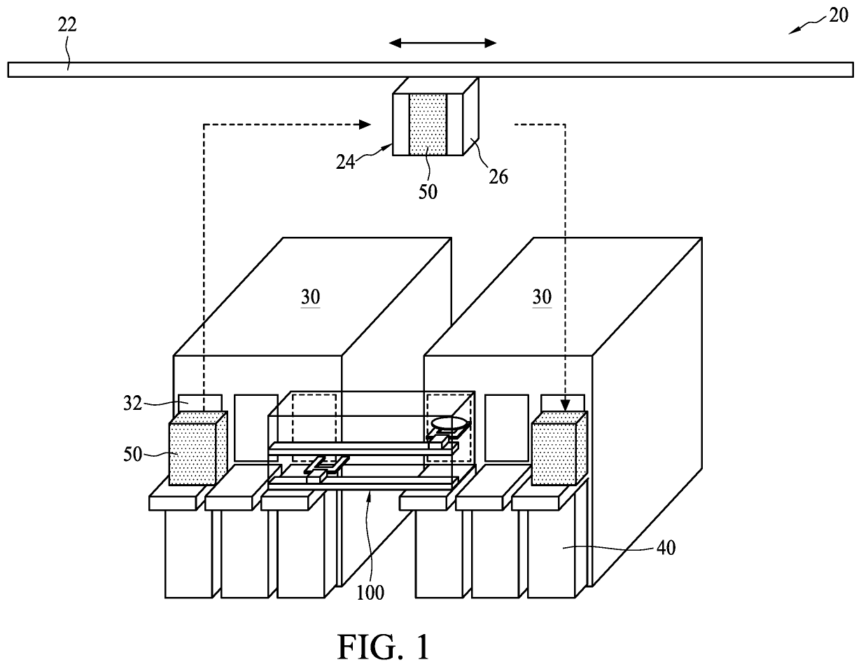

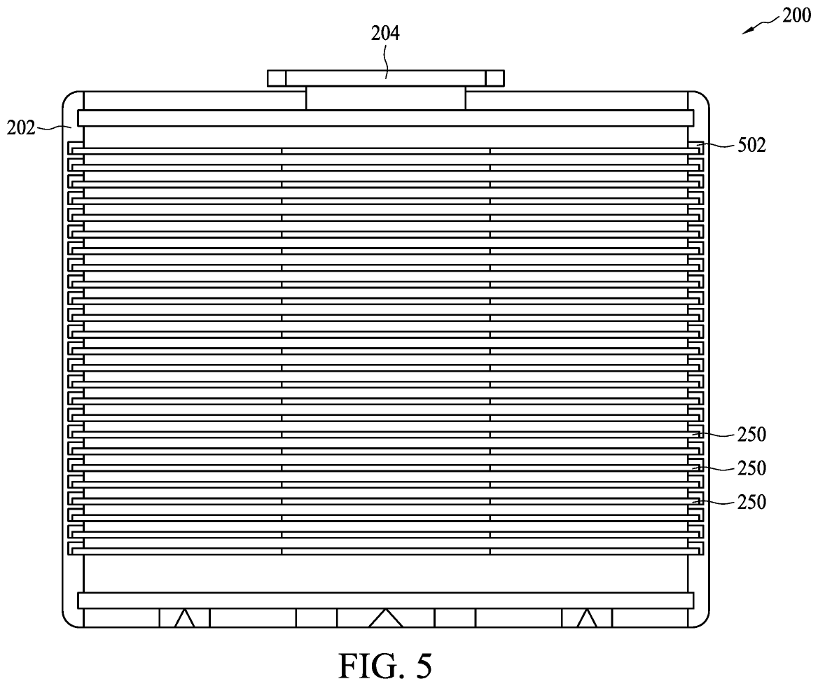

FIG. 1 is a schematic perspective diagrams of an overhead hoist transfer (OHT) system 20, in accordance with some embodiments of the present disclosure. The OHT system 20 may be shown as part of an automated material handling system (AMHS) although other parts of the AMHS system are not shown in FIG. 1. The AMHS system may be deployed in one or more facilities of a semiconductor manufacturer for facilitating transport efficiency of semiconductor wafers or substrates. According to some embodiments of the present disclosure, the AMHS system, including one or more of the OHT system 20, is designed to aid in transporting one or more semiconductor wafers (not shown in FIG. 1, but illustrated as semiconductor wafers 250 in FIG. 5) such that a sequence of semiconductor manufacturing operations can be performed on each of the semiconductor wafers 250. The AMHS system is usually operated by a programmed automated control steps with minimal human intervention during the transporting and semiconductor manufacturing operations.

According to some embodiments of the present disclosure, the AMHS system includes various nodes such as an input port (not shown), an output port (not shown), one or more storage units (also referred to as stockers) or semiconductor processing tools 30, all of which collectively referred to herein as semiconductor tools. One or more OHT systems, including the OHT system 20, are constructed to interconnect the abovementioned nodes in order to transfer a semiconductor wafer 250 to a predetermined node at a predetermined time, or receive a semiconductor wafer 250 from a predetermined node at a predetermined time.

According to some embodiments of the present disclosure, the one or more semiconductor processing tools 30 are configured to perform specific processing operations, e.g., a photolithography operation, a coating operation, a deposition operation, a thermal operation, an etching operation, an ion implantation operation, a calibration operation, a measurement operation, an inspection operation, a pick-up operation, a bonding operation, a testing operation, a cleaning operation, a singulation operation, and the like.

According to some embodiments of the present disclosure, the OHT system 20 includes a network of tracks 22 (represented by a single track 22 shown in FIG. 1), a plurality of OHT vehicles 24 mounted on the tracks 22, and a plurality of wafer carriers 50. The network of tracks 22 are deployed along the routes connecting the different nodes, configured to hold the OHT vehicle 24 and guide the movement of the OHT vehicle 24 on the tracks 22. The tracks 22 may be constructed at an elevation over the floor of the semiconductor manufacturing facility or suspended from a ceiling and/or walls of the semiconductor manufacturing facility. According to some embodiments, the tracks 22 includes a monorail structure suspended from a ceiling and holds the OHT vehicle 24. The OHT vehicle 24 may include pulleys or other sliding members configured to be clamped into a trench of the track 22, and operable to slide or drive along the trench of the track 22.

The topology of the tracks 22 in the AMHS system may be formed to include a plurality of bays each including a set of nodes interconnected in a loop shape, and different bays are interconnected by one or more tracks 22 of inter-bay loops. Generally, the movement of the OHT vehicle 24 is categorized into intra-bay movement and inter-bay movement, wherein the intra-bay movement involves movements within a single bay, while the inter-bay movement involves movements across different bays through the inter-bay loops.

The wafer carrier 50 is carried by the OHT vehicle 24, thereby the semiconductor wafers 250 are transferred to various nodes of the AMHS system via the transferring of the wafer carrier 50. According to some embodiments of the present disclosure, the OHT vehicle 24 includes robotic arms configured to hold and move the wafer carrier 50 between the nodes of the AMHS system and the tracks 22. The OHT vehicle 24 may be further configured to control the accessing to the wafer carrier 50, e.g., to pick up, raise, lower, hold, and release the wafer carrier 50. According to some embodiments, the OHT vehicle 24 further includes a coupling member 26 to aid in engagement of the wafer carrier 50 with the nodes or the input/output port of the AMHS system. The coupling member 26 may include, e.g., hooks, flanges, rails, slots, and the like.

According to some other embodiments, the wafer carrier 50 is hermetically sealed or locked during the transfer process in order to keep a condition of low contamination and low moisture within the wafer carrier 50 so that the external influence caused to material properties of one or more material layers formed on the semiconductor wafer 250 can be minimized.

Referring to FIG. 1, the wafer carrier 50 generally includes an enclosure configured to contain one or more semiconductor wafers 250. The wafer carrier 50 can be any type of wafer carrier such as a SMIF (Standard Mechanical Interface) pod, FOUP (Front-open Unified Pod), or a reticle pod. Each wafer carrier 50 carries a plurality of wafers or a single reticle (also referred to as photomask or mask). According to some embodiments, a SMIF pod or a FOUP can carry approximately 10-25 semiconductor wafers.

According to some embodiments, each semiconductor processing tool 30 includes one or more load ports 40 configured to receive the wafer carrier 50. When the wafer carrier 50 is moved to rest on the load port 40, the semiconductor processing tool 30 and the robotic arms of the OHT vehicle 24 work together to facilitate accessing of the semiconductor wafer or reticle into or from the semiconductor processing tool 30. For example, the OHT vehicle 24 travels to a location over the semiconductor processing tool 30 and aligns with a load port 40 of the semiconductor processing tool 30. The OHT vehicle 24 lowers the wafer carrier 50 to the stage of the load port 40 and activates the receiving of the wafer carrier 50 by the load port 40. According to some embodiments of the present disclosure, the semiconductor processing tool 30 further includes one or more access doors 32, wherein the semiconductor wafer or reticle is loaded into or unloaded from the semiconductor processing tool 30 through the access door 32. According to some embodiments, the access door 32 is in a shape fitting the shape of the configuration of a door of the wafer carrier 50 to maintain the hermeticity of the wafer carrier 50 during the transfer of the semiconductor wafer or reticle moved into or out of the wafer carrier 50.

Referring now to FIG. 1, the AMHS system further includes a load port channel 100 provided between adjacent semiconductor processing tools 30. The load port channel 100 may include an enclosure having a first end and a second end connected to two load ports of the adjacent semiconductor processing tools 30. The load port channel 100 may further include a docking port disposed at each of the first end and the second end to interface with an access door 32 of each of the semiconductor processing tools 30. In some embodiments, the enclosure of the load port channel 100 has an elongated shape extending between the semiconductor processing tools 30. The cross section of the enclosure may include a square or rectangular shape. Other suitable configurations of the enclosure are also within the contemplated scope of the present disclosure.

The load port channel 100 is provided between closely arranged semiconductor processing tools 30 to facilitate the transfer of the semiconductor wafer 250 without the additional moving steps via the wafer carrier 50. According to some embodiments, the enclosure of the load port channel 100 includes parallel panels to move the semiconductor wafer 250 at different elevations of the access doors 32 between the adjacent semiconductor processing tools 30. According to some embodiments of the present disclosure, the hermetical condition at the interface between the load port 40 and the load port channel 100 is maintained to guarantee the condition of the semiconductor wafers 250 are maintained or affected at a minimized level during the transfer through the load port channel 100.

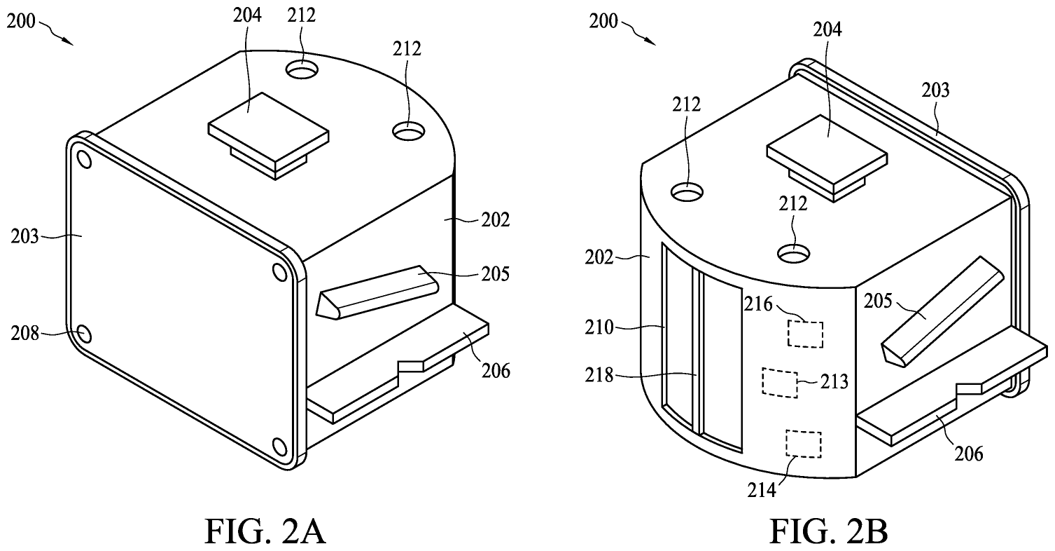

FIGS. 2A and 2B show schematic perspective diagrams of wafer carrier 200, in accordance with some embodiments of the present disclosure. According to some embodiments, the wafer carrier 200 is similar to the wafer carrier 50 shown in FIG. 1 and is a FOUP. Referring to FIG. 2A, the FOUP 200 includes a casing 202, a side door 203, a top handle 204, a side handle 205 and a side rail 206.

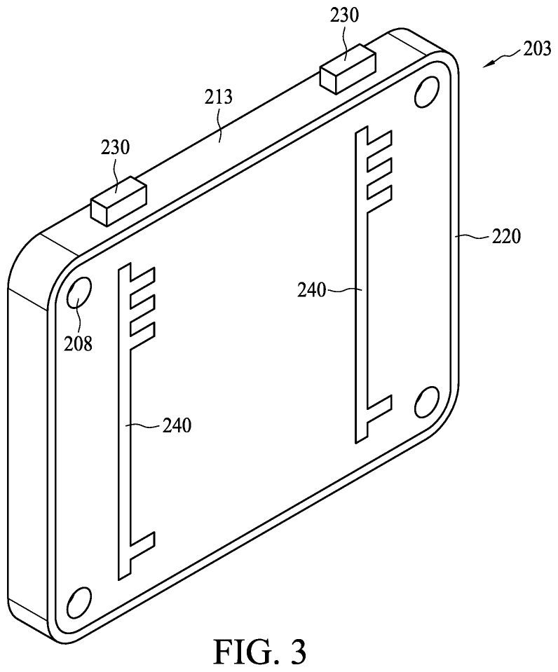

According to some embodiments, the side door 203 is provided on a first side, e.g., a backside, of the casing 202. The side door 203 is detachable from the casing 202 and configured to form a sealed or hermetical environment with the casing 202 in the enclosure of the wafer carrier 200 to keep the semiconductor wafer 250 in the wafer carrier 200 from contamination, oxygen, moisture, or other types of foreign particles. FIG. 3 is a perspective view of the side door 203, in accordance with some embodiments of the present disclosure. Referring to FIGS. 2A and 3, the side door 203 includes a body 213, one or more latch holes 208, a sealing member 220, one or more clamps 230, and a wafer holder 240. The sealing member 220 is affixed to the periphery of the side door 203 for keeping hermeticity when the side door 203 covers the opening of the casing 202 by engagement to the casing 202. According to some other embodiments, the sealing member 220 includes an elastic materials, e.g., rubber or other types of polymer materials. According to some embodiments, the sealing member 220 may be alternatively or additionally arranged on the periphery of the opening on the casing 202 to form a hermitical enclosure with the sealing member 220.

According to some embodiments, the clamp 230 is arranged along a thickness direction of a periphery of the side door 203. The clamp 230 may be used to fix the side door 203 to a corresponding clamping hole on the casing 202 before a fastener is fastened to the casing 202 through the latch holes 208. The clamp 230 is arranged to protrude from the periphery of the side door 203. According to some embodiments, one or more fastening members, e.g., screws (not shown), are utilized to fasten the side door 203 to the casing 202 to ensure the hermiticity of the enclosure of the wafer carrier 200 during the transport of the wafer carrier 200.

According to some embodiments, the semiconductor wafers 250 are contained within the wafer carrier 200, where the semiconductor wafers 250 are arranged in a horizontal orientation and parallel to each other. Each of the semiconductor wafers 250 are spaced apart from the sidewall of the wafer carrier 200 and spaced apart from each other by a uniform distance, e.g., 8-15 millimeters across the width of the semiconductor wafers 250. According to some embodiments, the wafer holder 240 is provided to press the semiconductor wafers 250 from the lateral side to ensure the semiconductor wafers 250 are contained at fixed locations. The wafer holder 240 may include two vertical holding beams and teeth extending from the holding beams to support or contain the semiconductor wafers 250. The wafer holder 240 along with the holding beams and the teeth may be formed of flexible materials.

Referring to FIG. 2A and FIG. 2B, the side handle 205 is arranged on a lateral side of the casing 202 and operable to the lifting up of the wafer carrier 200 1 by hand. According to some embodiments, the top handle 204 is used to be gripped by the OHT vehicle 24 shown in FIG. 1 during the transport of the wafer carrier 200 or 50. The top handle 204 may include protrusions extending laterally over the top surface of the casing 202 for facilitating gripping of the casing 202 by the robotic arms of the OHT vehicle 24. According to some embodiments, the side rail 206 is used by robots in other transport applications.

According to some embodiments, the casing 202 and the side door 203 are formed of rigid materials, such as plastics, metal, or other suitable materials, for providing rigidity of the wafer carrier 200 and protecting the semiconductor wafer 250 within the wafer carrier 200 from foreign forces. Moreover, some material layers of the semiconductor wafer 250 are sensitive to light and is susceptible to property changes due to exposure to light. Therefore, the casing 202 and the side door 203 are usually made of opaque materials to block light outside of the wafer carrier 200 from entering into the wafer carrier 200. However, when the AMHS system or the individual wafer carriers 200 suffers unexpected strike, shock or damage, e.g., an earthquake, there is a need to inspect those semiconductor wafers 250 within the wafer carriers 200 as quick as possible. Under such condition, the process of unloading the side door 203 from the casing 202 is time-consuming since the side door 203 is fastened to the casing 202 by fastening members. Further, shifting or turning the wafer carrier 200 or the side door 203 without the real-time information of the semiconductor wafers 250 after the wafer carrier 200 is shaken out of place may cause more damage by turning the semiconductor wafer 250 around.

To address the abovementioned problems, the proposed wafer carrier 200 includes an inspection window 210 arranged on a lateral side, e.g., a front side or a lateral side, of the casing 202. According to some embodiments, the inspection window is disposed on the side door 203. The inspection window 210 is configured as a bi-state inspection window having two display modes. According to some embodiments, the inspection window 210 is formed of a liquid crystal material, where light is blocked from passing through the inspection window 210 under a first state or mode, e.g., an opaque mode, and is allowed to pass through the inspection window 210 under a second state or mode, e.g., a transparent mode.

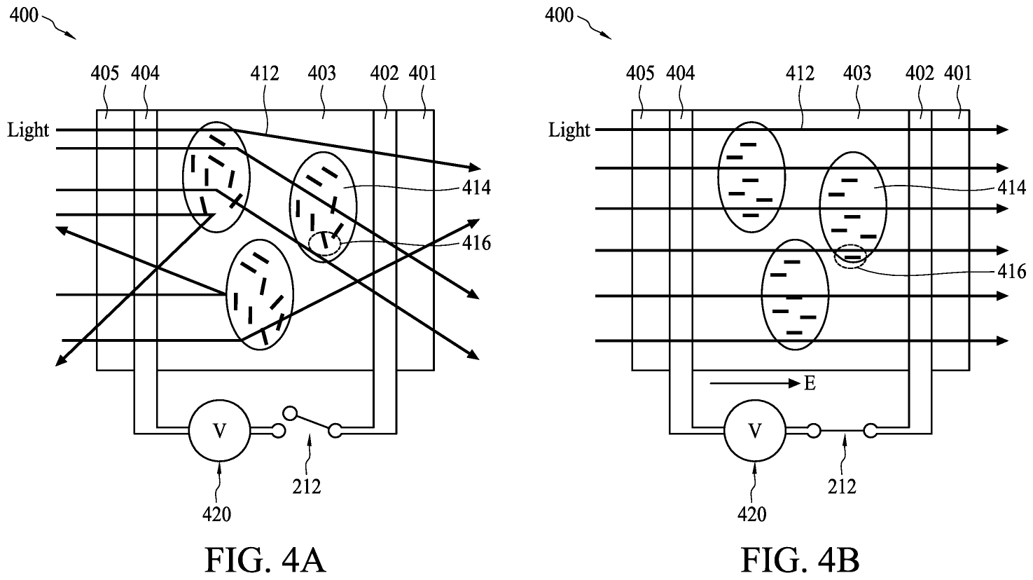

FIGS. 4A and 4B show cross-section views of an inspection window 400 in different modes, in accordance with some embodiments of the present disclosure. The inspection window 400 may be similar to the inspection window 210 shown in FIG. 2B. The inspection window 400 is configured to be switched between two modes or states to serve as a bi-state inspection window. The inspection window 400 may include a first substrate layer 401, a first conductive layer 402, a liquid crystal layer 403, a second conductive layer 404, and a second substrate layer 405 arranged in a stack.

The first substrate layer 401 or the second substrate layer 405 may be used as a frame or container for accommodating the first conductive layer 402, the second conductive layer 404 and the liquid crystal layer 403. According to some embodiments, the first substrate layer 401 or the second substrate layer 405 is formed of a rigid and transparent material, such as polyethylene terephthalate (PET), Polyethylene terephthalate glycol (PETG), polycarbonate, acrylic, polyvinyl chloride (PVC), glass, and the like. Light can pass through the inspection window 400 due to the transparency of the first substrate layer 401 and the second substrate layer 405.

According to some embodiments, the first conductive layer 402 serves as a first electrode of the liquid crystal layer 403. Similarly, the second conductive layer 404 serves as a second electrode of the liquid crystal layer 403. The first conductive layer 402 and the second conductive layer 404 may be formed by coating a conductive film on the surface of the first substrate layer 401 and the second substrate layer 405, respectively. The conductive film used in the first conductive layer 402 and the second conductive layer 404 generally includes a transparent conductive material, such as indium tin oxide (ITO), indium gallium zinc oxide (IGZO), or other transparent metallic oxide. The coating film of the first conductive layer 402 or the second conductive layer 404 may be patterned based on different requirements.

The liquid crystal layer 403 is formed in a space between the first conductive layer 402 and the second conductive layer 404. According to some embodiments, the liquid crystal layer 403 includes a plurality of groups 414 of liquid crystal molecules 416 encapsulated in a polymer material 412. According to some embodiments, the polymer material 412 may include a transparent material, e.g., polyvinyl alcohol, polyvinyl acetate, acrylic copolymers, or the like. In some embodiments, each of the groups 414 of the liquid crystal molecules 416 includes a droplet shape, a spherical shape, a cobblestone shape, or the like. The groups 414 of the liquid crystal molecules 416 are dispersed in the polymer material 412, as shown in FIGS. 4A and 4B. The transparent polymer material may separate the liquid crystal droplets in the liquid crystal layer 403. According to some embodiments, the optical performance of the liquid crystal molecules 416 within each group 414 is not affected when it is wrapped by the polymer material 412.

According to some embodiments, the inspection window 400 is configured as a bi-state inspection window, in which the inspection window 400 is set at the opaque mode when the first conductive layer 402 and the second conductive layer 404 are substantially free of biasing voltages, and set at the transparent mode when a voltage source 420 having a voltage V is applied to two ends of the liquid crystal layer 403, e.g., the first conductive layer 402 and the second conductive layer 404. Referring to FIGS. 2A and 2B, the wafer carrier 200 includes one or more switches or electrodes 212. Referring to FIG. 4B, the voltage V of the voltage source 420 can be applied to the inspection window 210 through the electrodes 212. In that case, the electrodes 212 serve as power contacts configured to receive electrical potential values of the voltage source 420, such as a positive voltage V and a ground voltage, to establish the voltage V between the two ends of the liquid crystal layer 403. The voltage source 420 may be on the outside of the wafer carrier 200 and electrically coupled to the inspection window 210 or 400 through the electrodes 212.

According to some embodiments, the voltage V is in a range between about 5 volts and about 200 volts, between about 5 volts and about 50 volts, or between about 10 volts and between about 50 volts.

According to some other embodiments, the voltage source 420 is a power storage unit, e.g., a battery capable of providing power with the supply voltage V. The power storage unit 420 may be electrically coupled to the two ends of the liquid crystal layer 403, e.g., the first conductive layer 402 and the second conductive layer 404, through the switches 212. The power storage unit 420 may be embedded in the wafer carrier 200. When the switches 212 is switched on, electrical current is conducted to the first conductive layer 402 and the second conductive layer 404 from the power storage unit through the switches 212.

Referring to FIG. 4A, the first conductive layer 402 and the second conductive layer 404 are not biased by any voltage sources. According to some embodiments, the switches 212 are configured to be in an open-circuit state. Alternatively, the electrodes 212 are electrically coupled to the first conductive layer 402 and the second conductive layer 404, but are not coupled to the voltage source 420. As shown in FIG. 4A, when no external biasing voltage is applied, the long axes of the liquid crystal molecules 416 are oriented randomly in different directions. At the same time, light entering the inspection window 400 from one of the first substrate layer 401 and the second substrate layer 405 are dispersed by the randomly-arranged liquid crystal molecules 416. Some portions of the light may travel through the other one of the first substrate layer 401 and the second substrate layer 405 in random directions to form dispersion. Some other portions of the light may be reflected back to the entry of the one of first substrate layer 401 and the second substrate layer 405 in random directions as well. Since the light are mostly dispersed by the random liquid crystal molecules 416, the inspection window 400 would be in an opaque state or mode when viewed from either side of the inspection window 400.

Referring to FIG. 4B, the first conductive layer 402 and the second conductive layer 404 are biased at the biasing voltage V. When the biasing voltage V is applied, the long axes of the liquid crystal molecules 416 are aligned to the direction of the electrical field E generated between the first conductive layer 402 and the second conductive layer 404. Thus, the randomly-arranged liquid crystal molecules 416 would not disperse light passing therethrough, but rather allow light to pass through with a uniform direction between the first conductive layer 402 and the second conductive layer 404. The light entering the inspection window 400 from one of the first substrate layer 401 and the second substrate layer 405 would successfully exit the inspection window 400 form the other one of the first substrate layer 401 and the second substrate layer 405. As a result, the inspection window 400 would be configured in a bright state or in the transparent mode when viewed from either side of the inspection window 400 in response to a suitable biasing voltage V.

Referring to FIG. 2B, according to some embodiments, the wafer carrier 200 further includes a sensor 214 disposed within the casing 202 or on the inner sidewall of the casing 202. According to some embodiments, the sensor 214 is capable of sensing a shaking or an abrupt movement due to an unexpected external force, such as an earthquake or a fall of the wafer carrier 200. The sensor 214 may be an accelerometer or a gyroscope configured to sense the abrupt or accelerated movement. According to some other embodiments, the wafer carrier 200 further includes a transceiver 216 configured to receive a signal of emergent event, such as power outage or an earthquake. The transceiver 216 may include a wireless transmitter and a wireless receiver to communicate a notification signal or a triggering signal. According to some embodiments, the switch 212 may be switched by hand or electrically switched automatically in response to a triggering signal transmitted by the transceiver 216 in response to a notification signal provided to the transceiver 216 or provided by the sensor 214.

During operation, when the wafer carrier 200 stores one or more semiconductor wafers 250, the switch 212 is caused to switch to an opaque mode, and no voltage is applied to the first conductive layer 402 and the second conductive layer 404 (see FIG. 4A) of the inspection window 210 or two ends of the liquid crystal layer 403. The inspection window 400 is closed or darkened by blocking of light from the outside of the wafer carrier 200. Further, during a predetermined time at a scheduled time interval, or in response to an emergent event such as an earthquake or power outage caused to the AMHS system, the inspection window 400 is electrically switched to the transparent mode through turning-on of the switches 212 in response to receiving the notification signal sent by the transceiver 216.

According to some embodiments, the wafer carrier 200 further includes a controller 113 electrically coupled to at least one of the switch 212, the sensor 214, and the transceiver 216. The controller 113 may be configured to receive the sensing result of the sensor 214 or the notification signal of the transceiver 216, and configured to transmit a triggering signal to turn on the switch 212 for applying the voltage V to the inspection window 400, such that the condition of the semiconductor wafers 250 can be inspected by human or machine. According to some embodiments, the controller 113 is configured to transmit the triggering signal to a management unit, e.g., a central control room of the semiconductor manufacturing facility. The controller 113 may be constructed by a microcontroller, a processor, a field-programmable gate array (FPGA), or other suitable hardware.

Referring to FIG. 2B, according to some embodiments, the wafer carrier 200 further includes a camera assembly 218 configured to generate an image of the interior of the wafer carrier 200 when the inspection window 210 is set at the transparent mode. According to some embodiments, the camera assembly 218 may include one or more of light sources and one or more of image sensors, each pair of the light source and the image sensor is configured to generate an image of a portion of the interior of the wafer carrier 200. The light sources each may include a light-emitting diode or other light-emitting devices, and the image sensors each may include a photodiode or other suitable image-generating sensors. The light sources and the image sensors may be arranged on the outside of the inspection window 210. According to some embodiments, the inspection window 210 extends in a vertical direction of the front side of the casing 202 to expose the stack of semiconductor wafers 250 from top to bottom. The light sources and the image sensors may also extend from the top to the bottom of the inspection window 210 along the longitudinal axis of the inspection window 210 to capture a whole view of the stack of semiconductor wafers 250. The generated image of the wafer carrier 200 may be transmitted to the controller 113 for performing a check of the damage status. According to some embodiments, the transparent mode of the wafer carrier 200 also helps engineers of the semiconductor manufacturing facility to inspect the status of the semiconductor wafers 250 within the wafer carrier 200 as quick as possible at the scene. The process of waiting for generation and transmission of wafer carrier images can be saved.

FIG. 5 shows a schematic diagram of an interior view of the wafer carrier 200, in accordance with some embodiments of the present disclosure. The wafer carrier 200 may include a wafer holder 502 configured to support and hold a plurality of semiconductor wafers 250. According to some embodiments, the semiconductor wafers 250 are arranged in a horizontal direction and spaced apart from each other by a fixed distance. Therefore, in a normal condition without any damage, the image sensors of the camera assembly 218 can capture an image of the semiconductor wafers 250, as shown in the central part of FIG. 5, showing a view of parallel and thin slabs with substantially equal widths and thickness. The image captured by the image sensors may also capture an image of parallel and thin slabs with substantially equal spacing values across the widths of the semiconductor wafers 250.

If any one of the semiconductor wafers 250 is damaged due to being shifted out of place, or breaks due to the emergent event, such damaged semiconductor wafer 250 may not maintain at the horizontal level, or may not remain as one piece along the horizontal range between the two opposite sidewalls of the casing 202. According to some embodiments, the damaged semiconductor wafer 250 may break and the broken pieces may be slanted or collide with other semiconductor wafer 250. As a result, the captured image may not show a perfect view of parallel and thin slabs which are spaced apart by substantially equal spacings. According to some embodiments, the controller 113 may include an image recognition module configured to perform image recognition. An initial damage assessment of the semiconductor wafers 250 can be conducted based on a comparison of the captured image with a reference image of the wafer carrier 200 obtained from an image library, in which the reference image is captured in a normal condition of the wafer carrier 200 without any emergent event. Through the sensing and image recognition performed by the sensor 214, the transceiver 216, the camera assembly 218 and the image recognition module in the controller 113, the impact of the emergent event (e.g., an earthquake) on the semiconductor wafers 250 in the middle of the production line can be obtained within a short time, and the loss of the semiconductor manufacturing facility can be evaluated in an efficient manner.

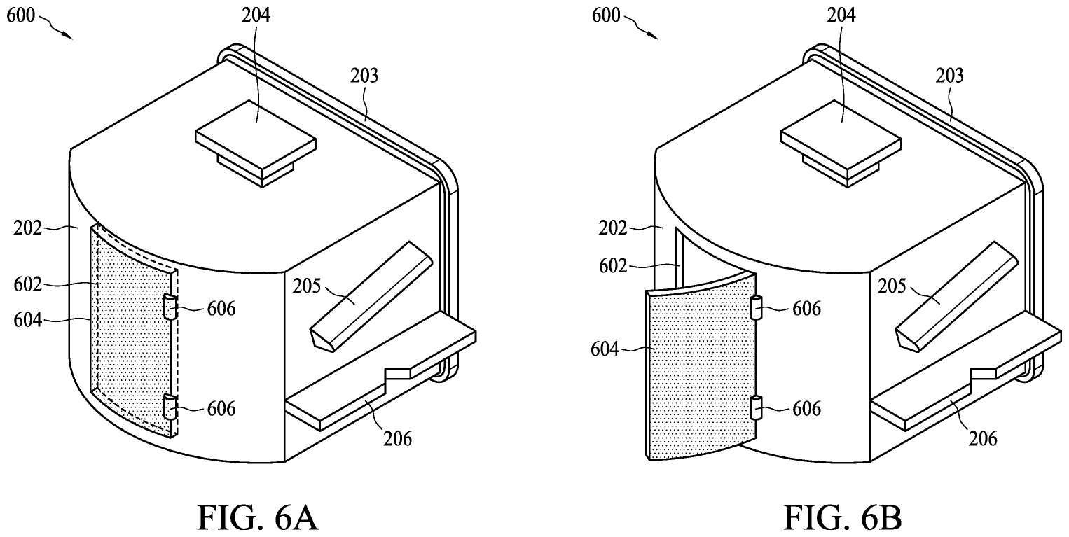

FIGS. 6A and 6B show a wafer carrier 600 in different usage modes, in accordance with some embodiments of the present disclosure. The wafer carrier 600 may be similar to the wafer carrier 50 or 200, and these similar features will not be repeated for brevity. The wafer carrier 600 includes an inspection window 602 and a cover 604 disposed over the inspective window 602 on a side of the casing 202. The cover 604 is referred to herein as a pivot-type cover. According to some embodiments, the inspection window 602 has a size similar to or greater than that of the inspection window 210 shown in FIG. 2B. The inspection window 602 is different from the inspection window 210 in that the inspection window 602 is made of a material always transparent, e.g., glass or a transparent plastic material such as polymethyl methacrylate (PMMA), or the like. In contrast, the cover 604 is formed of an opaque material, e.g., metal, opaque plastic such as acrylonitrile butadiene styrene (ABS), or the like, capable of blocking light from entering the inside of the wafer carrier 600 through the inspection window 602. According to some embodiments, the cover 604 is pivotally coupled to the casing 202 through one or more joints or pivots 606. The inspection window 602 may be closed by covering of the cover 604 on the surface of the inspection window 602 through clamping mechanism (not shown), e.g., a stick or baffle, on the other side of the joints 606.

Referring to FIG. 6A, during a normal operation of the wafer carrier 600, the cover 604 covers the inspection window 602. Light is not allowed to pass through the inspection window 602 for ensuring that the semiconductor wafers 250 are not adversely impacted by light. Referring to FIG. 6B, the cover 604 can be opened whenever an emergent event, e.g., an earthquake, occurs. The condition of the semiconductor wafers 250 can be examined by human eyes in an efficient manner.

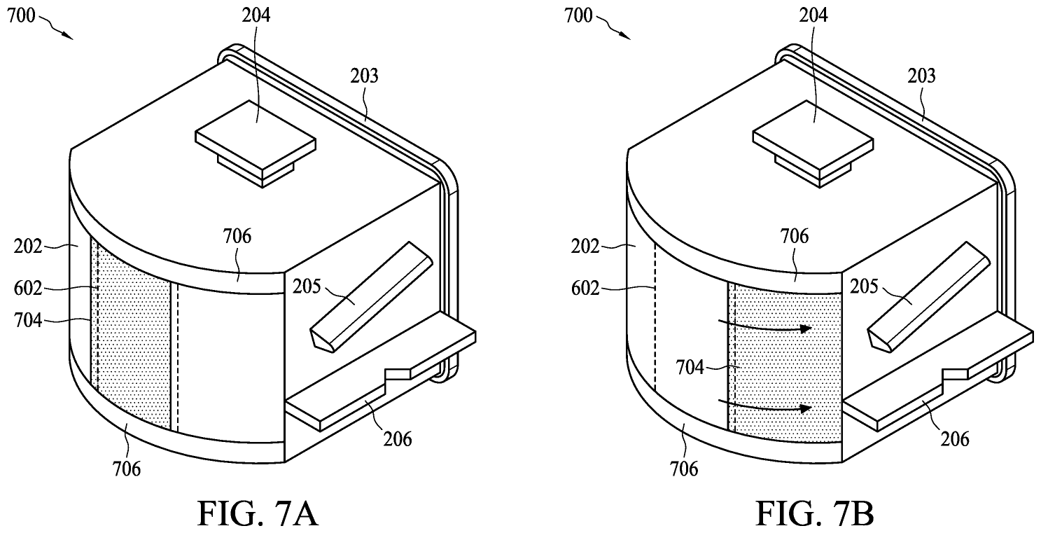

FIGS. 7A and 7B show a wafer carrier 700 in different usage modes, in accordance with some embodiments of the present disclosure. The wafer carrier 700 may be similar to the wafer carrier 50, 200 or 600, and these similar features will not be repeated for brevity. The wafer carrier 700 includes the inspection window 602 and a cover 704 covering the inspection window 602 on a side of the casing 202. The cover 704 is referred to herein as a slide-type cover. The cover 704 is formed of an opaque material, e.g., metal, opaque plastic such as acrylonitrile butadiene styrene (ABS), or the like, capable of blocking light from entering the inside of the wafer carrier 700 through the inspection window 602. The wafer carrier 700 may further includes tracks 706 on the upper side or the bottom side, or both sides, of the outer sidewall of the casing 202. The cover 704 is configured to slide horizontally along the tracks 706 to open or close the inspection window 602.

Referring to FIG. 7A, during a normal operation of the wafer carrier 700, the cover 704 covers the inspection window 602 by sliding over to fully overlap the inspection window 602. Light is not allowed to pass through the inspection window 602 for ensuring that the semiconductor wafers 250 are not adversely impacted by light. Referring to FIG. 7B, the cover 704 can be moved horizontally to expose the inspection window 602 whenever an emergent event, e.g., an earthquake, occurs. The condition of the semiconductor wafers 250 can be examined by human eyes in an efficient manner.

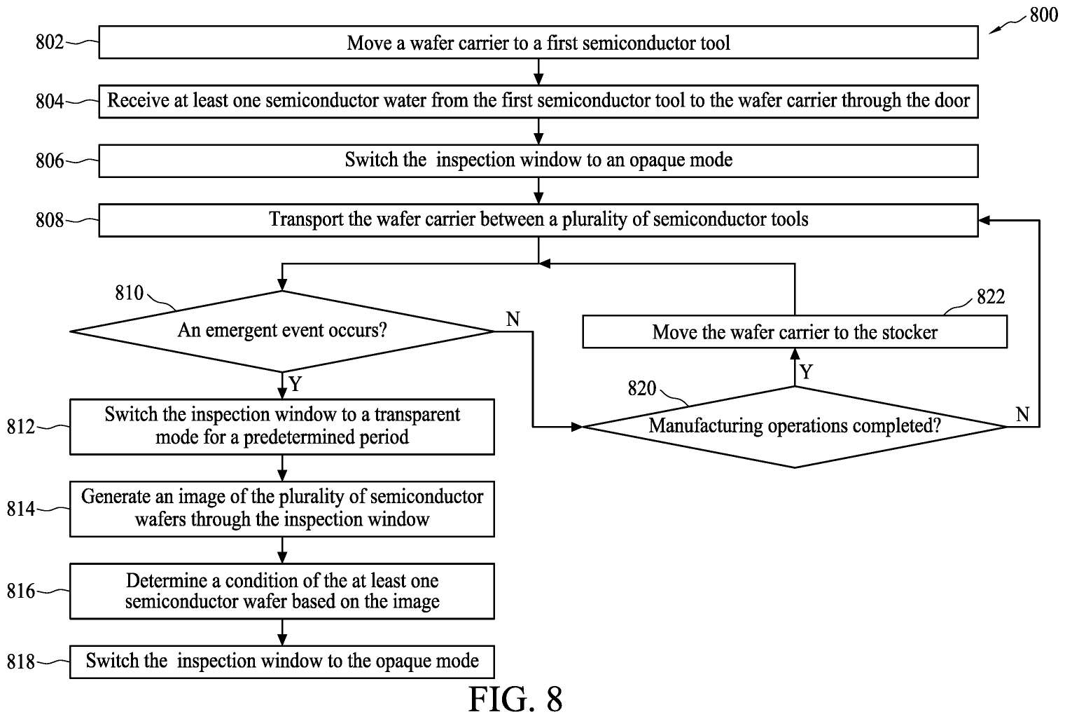

FIG. 8 is a flowchart of a method 800 of operating a wafer carrier, in accordance with some embodiments of the present disclosure. It shall be understood that additional steps can be provided before, during, and after the steps in method 800, and some of the steps described below can be replaced with other embodiments or eliminated. The order of the steps shown in FIG. 8 may be interchangeable. Some of the steps may be performed concurrently or independently.

At step 802, a wafer carrier is moved to a first semiconductor tool. According to some embodiments, the wafer carrier includes a door and an inspection window. At step 804, at least one semiconductor water is received from the first semiconductor tool to the wafer carrier through the door.

At step 806, the inspection window is switched to an opaque mode. At step 808, the wafer carrier is transported between a plurality of semiconductor tools, including the first semiconductor tool.

At step 810, it is determined whether an emergent event occurs according to, e.g., a sensing result, a notification signal or a triggering signal. If affirmative, at step 812, the inspection window is switched to a transparent mode for a predetermined period.

At step 814, an image of the at least one semiconductor wafer within the wafer carrier is generated through the inspection window. At step 816, a condition of the at least one semiconductor wafer is determined based on the image. The condition of the at least one semiconductor wafer may be determined based on an image recognition operation. Alternatively or additionally, the condition of the at least one semiconductor wafer may be determined directly through the inspection window by human. At step 818, the inspection window is switched to the opaque mode.

If it is determined that no emergent event occurs, at step 820, it is further determined whether the semiconductor manufacturing operations for the at least one semiconductor wafer is completed. If affirmative, at step 822, the wafer carrier is moved to the stocker along with the at least one semiconductor wafer.

According to some embodiments, the method 1000 loops to step 810 to check whether an emergent event occurs to continue examining the condition of the at least one semiconductor wafer.

In accordance with some embodiments of the present disclosure, a method is provided. The method includes: receiving at least one semiconductor wafer to a wafer carrier, wherein the wafer carrier has an inspection window arranged on a side of the wafer carrier; transporting the wafer carrier between a plurality of semiconductor tools; and in response to an emergent event, switching the inspection window to a transparent mode for a predetermined period.

In accordance with some embodiments of the present disclosure, a method is provided. The method includes: moving a wafer carrier to a first semiconductor tool, wherein the wafer carrier has a door and an inspection window arranged on the wafer carrier; receiving at least one semiconductor wafer to the wafer carrier from the semiconductor tool through the door; switching the inspection window to an opaque mode; in response to an emergent event, switching the inspection window to a transparent mode; generating an image of the at least one semiconductor wafer; and determining a condition of the at least one semiconductor wafer based on the image.

In accordance with some embodiments of the present disclosure, a wafer carrier includes a casing having a wafer holder configured to hold at least one semiconductor wafer; a detachable door, wherein the at least one semiconductor wafer are allowed to be accessed through the detachable door; and an inspection window arranged on a side of the casing, wherein the inspection window is configured to switch between a transparent mode and an opaque mode.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving at least one semiconductor wafer to a wafer carrier, wherein the wafer carrier has an inspection window arranged on a side of the wafer carrier;
transporting the wafer carrier between a plurality of semiconductor tools; and
in response to an emergent event, switching the inspection window to a transparent mode for a predetermined period.

2. The method of claim 1, further comprising generating an image of the at least one semiconductor wafer through the inspection window by an image sensor.

3. The method of claim 2, further comprising determining a condition of the at least one semiconductor wafer based on the image.

4. The method of claim 3, further comprising performing an image recognition operation to determine the condition of the at least one semiconductor wafer.

5. The method of claim 1, further comprising sensing an abrupt movement caused by the emergent event.

6. The method of claim 1, wherein the inspection window includes a liquid crystal layer configurable to be switched between the transparent mode and an opaque mode.

7. The method of claim 6, further comprising transmitting a triggering signal to apply a voltage on two ends of the liquid crystal layer of the inspection window.

8. The method of claim 6, wherein the liquid crystal layer includes a polymer material and a plurality of groups of liquid crystal molecules dispersed by the polymer material.

9. The method of claim 1, further comprising moving the wafer carrier to a stocker along with the at least one semiconductor wafer in response to no emergent event occurs.

10. The method of claim 1, further comprising continuing monitoring the wafer carrier as to whether any emergent event occurs.

11. A method, comprising:
moving a wafer carrier to a semiconductor tool, wherein the wafer carrier has a door and an inspection window arranged on the wafer carrier;
receiving at least one semiconductor wafer to the wafer carrier from the semiconductor tool through the door;
switching the inspection window to an opaque mode;
in response to an emergent event, switching the inspection window to a transparent mode;
generating an image of the at least one semiconductor wafer; and
determining a condition of the at least one semiconductor wafer based on the image.

12. The method of claim 11, wherein the inspection window comprises a liquid crystal layer including a plurality of liquid crystal droplets, wherein each of the liquid crystal droplets including liquid crystal molecules aligned to a same direction during the transparent mode.

13. The method of claim 12, wherein the inspection window further includes a first conductive layer and a second conductive layer disposed on two ends of the liquid crystal layer and configured to receive a biasing voltage that cause the transparent mode.

14. The method of claim 12, wherein the liquid crystal layer further comprises a transparent polymer material separating the liquid crystal droplets.

15. The method of claim 11, wherein the generating of the image comprises generating the image on an outside of the wafer carrier through the inspection window.

16. The method of claim 11, wherein the determining of the condition of the at least one semiconductor wafer comprises comparing the image with a reference image obtained from an image library.

17. The method of claim 11, wherein the image shows a view of an interior of the wafer carrier from a top of the wafer carrier to a bottom of the wafer carrier.

18. A wafer carrier, comprising:
a casing comprising a wafer holder configured to hold at least one semiconductor wafer;
a detachable door, wherein the at least one semiconductor wafer are allowed to be accessed through the detachable door; and
an inspection window arranged on a side of the casing, wherein the inspection window is configured to switch between a transparent mode and an opaque mode.

19. The wafer carrier of claim 18, wherein the inspection window includes a first substrate layer, a first conductive layer, a liquid crystal layer, a second conductive layer and a second substrate layer arranged in a stack.

20. The wafer carrier of claim 19, further comprises electrodes electrically coupled to the first conductive layer and the second conductive layer, the electrodes configured to receive a voltage to switch the inspection window to the transparent mode.
